(19) United States
(12) Patent Application Publication
(10) Pub. No.: US 2009/0041074 A1
(43) Pub. Date: Feb. 12, 2009

(54) Passivation of Vertical Cavity Surface Emitting Lasers

(75) Inventor: Nein-Yi Li, Albuquerque, NM (US)

Correspondence Address: Casey Toohey;Emcore Corporation, 1600 Eubank Blvd., SE, Albuquerque, NM, 87123, US

(73) Assignee: Emcore Corporation, Albuquerque, NM (US)

(21) Appl. No.: 11/835,834

(22) Filed: Aug. 8, 2007

(51) Int. Cl. H01S 5/02; H01L 21/02

(52) U.S. Cl. 372/43.01; 438/22

(57) ABSTRACT

A vertical cavity surface emitting laser including a substrate, a plurality of epitaxial layers formed on the substrate as an epitaxial stack, and a passivation layer at least partly covering the epitaxial stack including a plurality of sublayers at least some of which are composed of different materials. The composition and thicknesses of the sublayers are chosen to minimise the overall stress of the passivation layer and thereby to increase a mean time before the vertical surface emitting laser fails.

### BACKGROUND TO THE INVENTION

1. Technical Field

This invention relates to the passivation of vertical cavity surface emitting lasers (VCSELs) and in particular, to a VCSEL incorporating a passivation layer and a method of manufacturing such a device.

2. Description of the Related Art

Generally, VCSELs include an active region between two mirrors, disposed one after another to form a stack of epitaxial layers on the surface of a substrate wafer. An insulating region forces the current to flow through a small aperture, and the device lases perpendicular to the wafer surface (i.e., the “vertical” part of VCSEL).

VCSELs are susceptible to damage due to oxidation arising from moisture. Therefore, various arrangements are known for protecting these devices from moisture.

In a first known scheme for passivating a VCSEL, the device is encapsulated in an hermetic can. This suffers from the disadvantages that hermetic cans are relatively expensive and that the encapsulation presents manufacturing challenges.

In an further known scheme, a VCSEL device is provided with a passivation layer. For example, US application 2004/0179411 discloses the use of a paralene coating as a passivation layer. However, this process is expensive and is not readily applicable to small-scale manufacture. Furthermore, the associated manufacturing process requires careful and elaborate control.

US application 2004/0156410 discloses the use of two passivation layers, the first comprising silicon nitride (SiNₓ) and the second, deposited on top of the first, comprising silicon oxynitride (SiOₓN_{y}).

Generally, the efficacy of a passivation layer is related to the thickness thereof. In a further known VCSEL, a thin layer of SiN (˜60 to 260 nm) is covered by a thick layer of polyimide (˜2,500 nm) to passivate the VCSEL. The SiN and polyimide layers impose a tensile stress on the epitaxial and oxide layers of the VCSEL. With an increase in the thickness of the SiN or polyimide layers, the effective stress applied to the epitaxial or oxide layers increases. The release of this stress energy results in cracking apertures, exploded mesas, cracks in the dielectric and blisters around the mesa foothills. These deleterious effects are observed during device fabrication, particularly after thermal processes such as the polyimide curing process which occurs at about 400° C., the SiN layer deposition which occurs at about 230° C. or rapid thermal annealing which occurs at about 370° C.

### SUMMARY OF THE INVENTION

The present invention provides a method and structure for improving the hermeticity of a VCSEL by the use of low stress material to passivate the device. The use of low stress material provides a passivation layer less susceptible to failure.

According to a first embodiment, a VCSEL is provided, the VCSEL comprising a substrate, a plurality of epitaxial layers disposed on the substrate to form an epitaxial stack and a passivation layer at least partly covering said epitaxial stack, the passivation layer comprising a first and a second sublayer with opposing stresses, the sublayers being disposed to reduce a net stress of the passivation layer and thereby to increase a mean time before the vertical surface emitting laser fails.

According to a second embodiment, a method for producing a VCSEL is provided, the method comprising the steps of:

forming a plurality of epitaxial layers on a substrate to form an epitaxial stack;

at least partly covering the epitaxial stack with a passivation layer, the passivation layer comprising a first and a second sublayer with opposing stresses disposed to reduce a net stress of the passivation layer and thereby to increase a mean time before the vertical surface emitting laser fails.

Preferably, the first sublayer comprises a first material and the second sublayer comprises a second material wherein the stress of the first sublayer and the stress of the second sublayer are related to a thickness of the respective sublayer and wherein the stress of the first material is at least partially countered by the stress of the second material.

By setting the thicknesses of the sublayers, the net stress of the passivation layer is reduced. VCSELs incorporating the invention exhibit a marked improvement in withstanding high temperature and high humidity environments without cracking. VCSELs incorporating the invention exhibit an improved mean time before failure compared to known devices under similar operating conditions.

Preferably, the sublayers of the passivation layer are deposited by plasma-enhanced chemical vapour deposition, which is cheaper and easier to control that providing a hermetic can or a passivation layer comprising polyimide.

### BRIEF DESCRIPTION OF THE DRAWINGS

Further features and advantages of the present invention will become apparent from the following description of preferred embodiments thereof, presented by way of example only, and by reference to the accompanying drawings, wherein like reference numerals refer to like parts, and wherein:

FIG. 1a is a fragmentary, cross-sectional view on an enlarged scale of a semiconductor structure for an oxide-confined VCSEL according to an embodiment of the invention;

FIG. 1b is a fragmentary, cross-sectional view on an enlarged scale of a semiconductor structure for an oxide-confined VCSEL according to a further embodiment of the invention;

FIG. 2 is a fragmentary, cross-sectional detailed view of the semiconductor structure for the oxide-confined VCSELs of FIGS. 1a and 1b;

FIG. 3 is fragmentary, cross-sectional schematic view of a passivation layer of the oxide-confined VCSELs of FIGS. 1a and 1b;

FIG. 4 depicts a number of VCSEL structures with varying coverage of a polyimide sublayer;

FIG. 5 depicts a VCSEL structure according to an embodiment of the invention; and

FIG. 6 is a graph comparing the results of a stress test on an number of VCSEL structures.

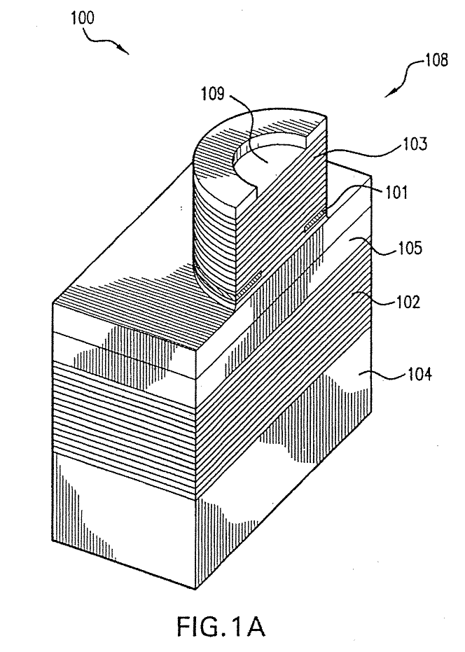

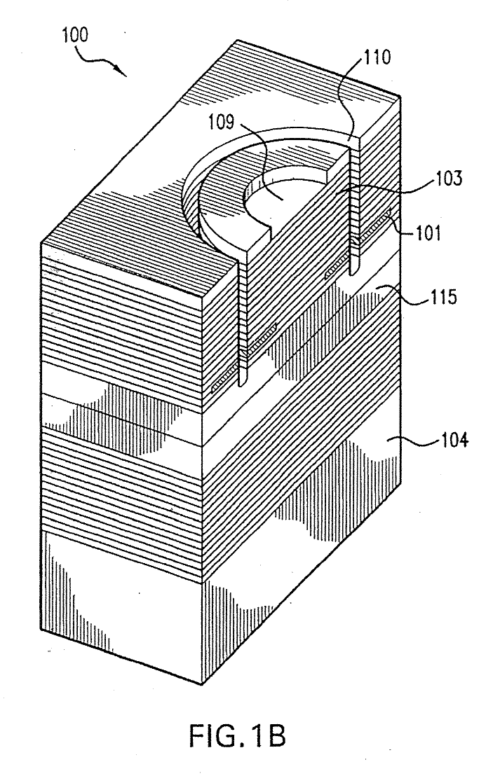

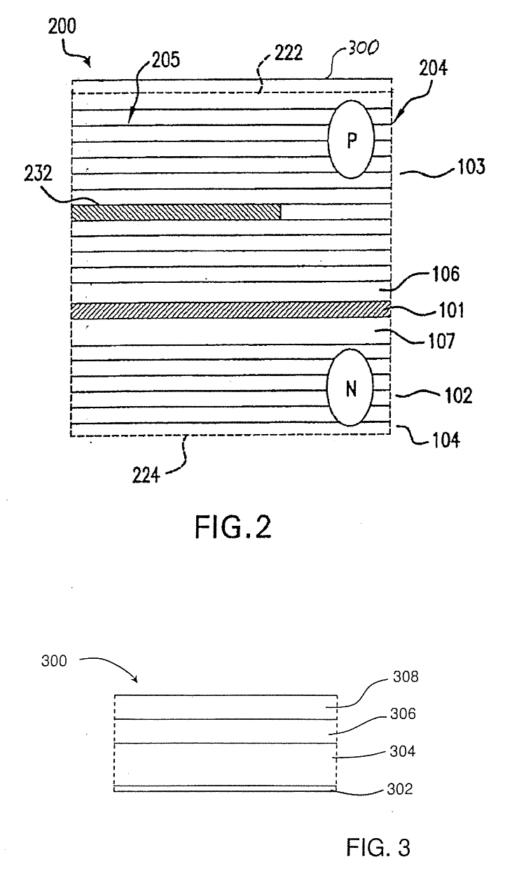

Referring to FIG. 1a there is shown a fragmentary, cross-sectional view of a semiconductor structure of an oxide-confined VCSEL according to an embodiment of the invention. In particular, the VCSEL 100 includes a laser cavity region 105 that is defined between a first semiconductor region 102 that forms a first mirror stack and a second semiconductor region 103 that forms a second mirror stack. The semiconductor regions 102 and 103 are disposed on a substrate 104 which may typically be p-type gallium arsenide. The cavity region 105 includes one or more active layers (e.g., a quantum well or one or more quantum dots). The active layers may be formed from AlInGaAs (i.e., AlInGaAs, GaAs, AlGaAs and InGaAs), InGaAsP (i.e., InGaAsP, GaAs, InGaAs, GaAsP, and GaP), GaAsSb (i.e., GaAsSb, GaAs, and GaSb), InGaAsN (i.e., InGaAsN, GaAs, InGaAs, GaAsN, and GaN), or AlInGaAsP (i.e., AlInGaAsP, AlInGaAs, AlGaAs, InGaAs, InGaAsP, GaAs, InGaAs, GaAsP, and GaP). Other quantum well layer compositions also may be used. The active layers may be sandwiched between a pair of spacer layers 106, 107, as shown in FIG. 2. First and second spacer layers 106, 107 may be composed of aluminium, gallium and arsenide and are chosen depending upon the material composition of the active layers. Electrical contacts (not shown) are provided to the structure to enable a suitable driving circuit to be applied to the VCSEL 100. The semiconductor layers deposited on the substrate 104 form an epitaxial stack.

The substrate 104 may be formed from GaAs, InP, sapphire (Al₂O₃), or InGaAs and may be undoped, doped n-type (e.g., with Si) or doped p-type (e.g., with Zn). A buffer layer may be grown on substrate 104 before VCSEL 100 is formed. In the illustrative representation of FIG. 1a, first and second mirror stacks 102, 103 are designed so that the laser light is emitted from the top surface of VCSEL 100; in other embodiments, the mirror stacks may be designed so that laser light is emitted from the bottom surface of substrate 104.

In operation, an operating voltage is applied to the electrical contacts to produce a current flow in the semiconductor structure. The current will flow through a central region of the semiconductor structure resulting in lasing in a central portion of cavity region 105. A confinement region defined by a surrounding oxide region 101 or ion implanted region, or both, provides lateral confinement of carriers and photons. The relatively high electrical resistivity of the confinement region causes electrical current to be directed to and flow through a centrally located region of the semiconductor structure. In particular, in this oxide VCSEL, optical confinement of photons results from a substantial reduction of the refractive index of the confinement region. A lateral refractive index profile is created that guides photons that are generated in cavity region 105. The carrier and optical lateral confinement increases the density of carriers and photons within the active region and increases the efficiency with which light is generated within the active region.

In some embodiments, the confinement region 101 circumscribes a central region of the VCSEL 100, which defines an aperture through which VCSEL current preferably flows. In other embodiments, oxide layers may be used as part of the distributed Bragg reflectors in the VCSEL structure.

The first and second mirror stacks 102 and 103 respectively each include a system of alternating layers of different refractive index materials that forms a distributed Bragg reflector (DBR). The materials are chosen depending upon the desired operating laser wavelength (e.g., a wavelength in the range of 650 nm to 1650 nm). For example, first and second mirror stacks 102, 103 may be formed of alternating layers of high aluminium content AlGaAs and low aluminium content AlGaAs. The layers of first and second mirror stacks 102, 103 preferably have an effective optical thickness (i.e., the layer thickness multiplied by the refractive index of the layer) that is about one-quarter of the operating laser wavelength.

The first mirror stack 102 may be formed as a mesa by conventional epitaxial growth processes, such as metal-organic chemical vapour deposition (MOCVD) or molecular beam epitaxy (MBE), followed by etching.

Once first mirror stack 102, active layer 105 and second mirror stack 103 are completed, the structure is patterned to form one or more individual VCSELs. The upper surface of second mirror stack 103 is provided with a layer of photoresist material according to any of the well known methods in the art. The photoresist layer is exposed and material is removed to define the position and size of a mesa. The mesa is then formed by etching mirror stack 103 by any suitable means known in the art, such as dry or wet etch processes. Typical dry etch processes use chlorine, nitrogen, and helium ions, and wet etch processes use sulphuric or phosphide acid etches. The mesa may range from 20 to 50 microns, but preferably about 28 microns in diameter, and be about three to five microns in height above the surface of the substrate.

FIG. 1b illustrates a perspective view of another VCSEL structure 100 to which the invention is applied, (this type of structure is represented in published U.S. Patent Application No. 2003/0219921 which is incorporated herein by reference). The VCSEL structure 100 includes an insulating region that can be formed by partial oxidation of a thin, high aluminium-content layer within the structure of an associated VCSEL mirror. FIG. 1b represents a schematic cross-sectional view of an oxide-isolated VCSEL 100 surrounded by a trench 110, as opposed to the mesa type structure 108 shown in FIG. 1a. As indicated in FIG. 1b, VCSEL 100 generally includes an emission aperture 107, an oxide confinement region 101 forming an aperture, and an active region 106.

FIG. 2 generally illustrates an enlarged portion of either FIG. 1a or FIG. 1b and schematically illustrates the location of an oxide layer in structure 200. Structure 200 represents a typical VCSEL confinement structure for an oxide-confined VCSEL. The right hand edge 204 of structure 200 represents the centreline of a VCSEL optical cavity. Note that such a VCSEL cavity generally possesses a radial symmetry.

A layer of dielectric material, such as silicon nitride (SiNₓ), is deposited over the entire surface of VCSEL 100 and an opening is etched through on the upper surface of mesa-shaped structure 108 to generally coincide with and define a light emitting area 109. A transparent metal contact layer is deposited in the emitting area and continued over mesa shaped structure 108 to define an electrical contact window and to provide sufficient surface for an external electrical contact. Generally, the transparent metal utilized is indium tin oxide (ITO), cadmium tin oxide, or the like.

The cavity region or quantum well regions 105 contain a P-N junction. Quantum well region 105 is located between bands 106 and 107 of VCSEL 100, which respectively represent p-type and n-type spacer layers that set the cavity length of the VCSEL. A portion of the p-type Bragg mirror can be located on the top 222 of the structure and a portion of the n-type Bragg mirror can also be located at the bottom 224 of VCSEL 100.

In oxide VCSEL structures, the wet thermal oxidation process forms an annular ring of aluminium oxide represented by the layer 232 in structure 200. The oxidation process also removes acceptor concentration from the surrounding layers.

The VSCEL 100 further includes a passivation layer 300 which is shown in greater detail in FIG. 3 and which includes a number of sublayers 302, 304, 306 and 308. Sublayer 302 is formed directly on top of second semiconductor region 103 or on top of the portion of the p-type Bragg mirror located on the top 222 of the structure (if included). Sublayer 302, in the embodiment shown, has a thickness of 39 nm and comprises SiOₓN_{y} (silicon oxynitride). Sublayer 304 comprises SiOₓN_{y} with a thickness of 220 nm formed on top of sublayer 302; sublayer 306 comprises SiNₓ (silicon nitride) with a thickness of 110 nm formed on top of sublayer 304; and sublayer 308 comprises a 110 nm thick sublayer of SiNₓ formed on top of sublayer 306. Sublayers 302, 304, 306 and 308 are deposited by plasma-enhanced chemical vapour deposition.

Although FIG. 3 illustrates a portion of the entire VCSEL structure 100, it is to be realised that the passivation layer 300 extends over the entire mesa-shaped structure 108 of the embodiment of FIG. 1a or the structure defined by trench 110 of the embodiment of FIG. 1b. In a further embodiment, passivation layer 300 extends substantially over the entire surface of the VCSEL structure 100.

In the embodiment illustrated, sublayers 304 and 306 provide the major contribution to improving the hermeticity of the VCSEL 100. The thickness of these layers is chosen and set so that the tensile stress of the SiNₓ sublayer 306 is counteracted by the compressive stress of the SiOₓN_{y} sublayer 304. In this regard, the VCSEL structure is formed so that the sublayer 304 has twice the thickness of sublayer 306.

In a further embodiment, a VCSEL is formed in which the combined thickness of sublayers 304 and 306 is approximately 800 nm, with sublayer 304 having twice the thickness of sublayer 306.

TABLE 1

| | Thickness | | Net Stress | Net Strain |
|---|---|---|---|---|
| | (nm) | Type | (MPa) | (nm * MPa) |
| Epitaxial | 1000 | Compressive | 100 | ~1 * 10⁶ |
| layers | | | | |
| SiNₓ | 55 | Tensile | −300 | ~2 * 10⁴ |
| SiNₓ | 260 | Tensile | −300 | ~8 * 10⁴ |
| Polyimide | 2500 | Tensile | −75 | ~2 * 10⁴ |
| SiNₓ | 110 | Tensile | −300 | ~3 * 10⁴ |
| SiOₓN_{y} | 39 | Compressive | 250 | ~1 * 10⁴ |
| SiOₓN_{y}/SiNₓ | 330 | Compressive | 20 | ~7 * 10³ |
| | (220 nm | | | |
| | SiOₓN_{y} | | | |
| | and 110 nm SiNₓ) | | | |

Table 1 compares the net stress and net strain for sublayers of various thicknesses and compositions used in the passivation of a VCSEL.

In the embodiments of FIGS. 1a, 1b, 2 and 3, the sublayers 304 and 306 have a net strain of approximately 7×10³ nm*MPa (corresponding to the lowermost entry in Table 1), which is a reduction of approximately 1×10⁵ nm*MPa over a passivation layer comprising SiNₓ and polyimide. This results in a three-fold improvement in the hermeticity of the VCSEL 100 over a similar structure employing a passivation layer comprising polyimide.

A VCSEL according to an embodiment of the invention was subjected to a 120° C., 100% humidity test for 56 hours and to a 85° C. , 85% humidity test for 446 hours without exhibiting any cracking apertures or blisters.

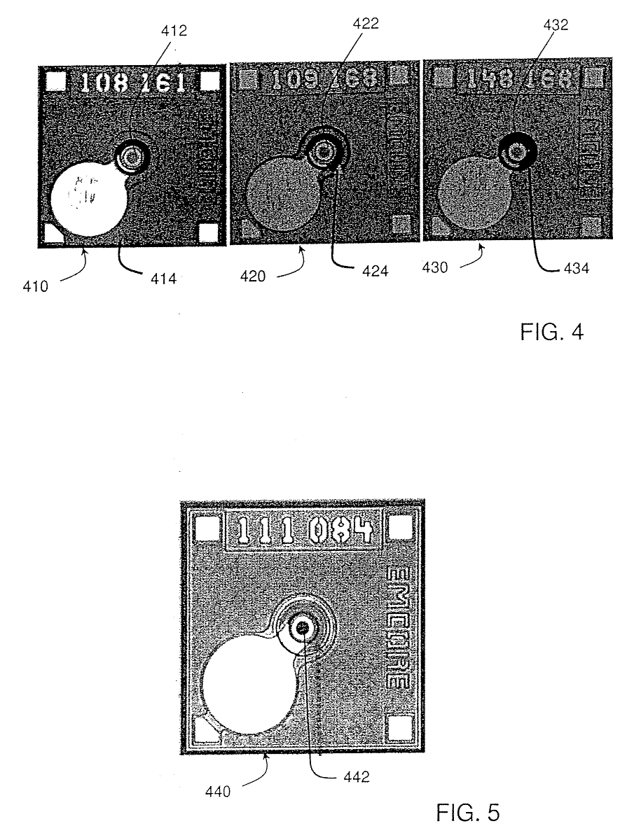

FIG. 4 illustrates three VCSEL structures 410, 420 and 430 having a passivation layer with the same structure and dimensions as that illustrated in FIG. 3 with the addition of a sublayer of polyimide of varying dice coverage over the three illustrated structures. The VCSEL structures 410, 420 and 430 have corresponding mesa structures 412, 422 and 432. In VCSEL structure 410 the entire surface of the dice has been coated with sublayer 414 of polyimide. In VCSEL structure 420, the polyimide sublayer 424 covers a substantially reduced area of the dice, whereas in VCSEL structure 430, the polyimide sublayer 434 only covers corresponding mesa structure 434 and a relatively small surrounding area.

FIG. 5 illustrates a VCSEL structure 440 with corresponding mesa structure 442. VCSEL structure 440 is formed so that the sublayers of the passivation layer corresponding to sublayers 304 and 306 of FIG. 3 have a combined thickness of approximately 800 nm. Furthermore, the VCSEL structure 440 does not include a sublayer of polyimide. Other than the two mentioned differences, the VCSEL structure 440 is similar to the VCSEL structures 410, 420 and 430 of FIG. 4.

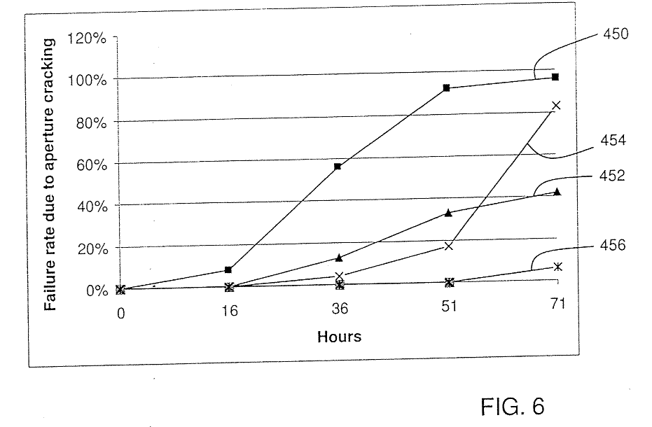

FIG. 6 is a graph where the performance in a 120° C., 120% humidity test at 2 atmospheres of the VCSEL structures 410, 420 and 430 of FIG. 4, and 440 of FIG. 5, are compared at various stages of the test up to 71 hours. Line 450 corresponds to VCSEL structure 410; line 452 corresponds to VCSEL structure 420; line 454 corresponds to VCSEL structure 430, and line 456 corresponds to VCSEL structure 440.

TABLE 2

| | Number | | | | | |
|---|---|---|---|---|---|---|
| | of | | | | | 71 |
| Polyimide | Dice | 0 hours | 16 hours | 36 hours | 51 hours | hours |
| Large | 48 | 0% | 8% | 56% | 92% | 96% |
| Medium | 24 | 0% | 0% | 13% | 33% | 42% |
| Small | 24 | 0% | 0% | 4% | 17% | 83% |
| None | 72 | 0% | 0% | 0% | 0% | 6% |

The data plotted in the graph of FIG. 6 is set out in Table 2. As illustrated by the graph of FIG. 6, the VCSEL structure without polyimide (line 456) exhibits a substantially reduced incidence of aperture cracking at all stages of the test.

TABLE 3

| | | | | | No. of | | No. of | |
|---|---|---|---|---|---|---|---|---|
| | | | | No. | dice | | dice | No. of dice |
| | | | No. | of | with | No. of | with | with |
| | Mesa | Polyimide | of | failed | aperture | dice with | pad | mechanical |
| Wafer | size | coverage | dice | dice | cracking | blistering | lifting | damage |
| EX3337W1 | Small | Medium | 24 | 19 | 10 | 1 | 9 | 0 |
| EX3337W1 | Small | Small | 24 | 22 | 20 | 0 | 0 | 2 |
| EX3337W1 | Large | Large | 24 | 24 | 23 | 0 | 1 | 0 |
| EX3337W1 | Small | Large | 24 | 24 | 23 | 0 | 1 | 0 |
| EX3338W2 | Large | None | 24 | 5 | 2 | 0 | 0 | 3 |
| EX3338W2 | Small | None | 24 | 4 | 2 | 0 | 1 | 1 |

Table 3 sets out data collected in a 120° C., 100% humidity test conducted for 71 hours on VCSEL wafers having differing structures. The VCSEL wafer EX3337W1 corresponds in structure to the VCSEL illustrated in FIG. 4, having adjacent SiOₓN_{y} and SiNₓ sublayers with a combined thickness of 330 nm and with a polyimide sublayer. The three different types of the EX3337W1 wafer listed in the Table have varying degrees of coverage of a polyimide sublayer. The EX3338W2 wafers correspond in structure to the VCSEL illustrated in FIG. 5 having adjacent SiOₓN_{y} and SiNₓ sublayers with a combined thickness of about 800 nm and do not have a polyimide sublayer. To test further variables, wafers with varying mesa sizes were produced and compared. Those wafers listed with a “large” mesa size had a mesa measuring 42 μm and those listed with a “small” mesa size had a mesa measuring 28 μm.

It was observed during the test represented by the data of Table 3 that the failures of the wafers with a polyimide sublayer were due to aperture cracking and pad lifting, whereas the wafers without a polyimide sublayer withstood the test significantly better. Furthermore, no significant difference in the hermeticity of those wafers with small mesa sizes was observed over those with large mesa sizes. The test further verified that VCSEL structures without a polyimide sublayer display a significant improvement in hermeticity over those which include a polyimide sublayer.

As previously stated, this improvement is due to the minimised net stress of the passivation layer of the VCSEL structures which do not include a polyimide sublayer. The addition of a polyimide sublayer increases the stress, thereby rendering the corresponding VCSEL structure more susceptible to aperture cracking.

It is to be realised that the invention is not limited to the use of silicon nitride and silicon oxynitride sublayers in the passivation layer 300 and that other low-stress materials may be used. Furthermore, it is to be realised that the thicknesses of the sublayers 302, 304, 306 and 308 given above are particular to the embodiment described. In further embodiments the thicknesses of these sublayers will vary. An important aspect of the invention is that the thicknesses of these sublayers is set to minimise the net stress of the passivation layer.

Furthermore, the area of the dice covered by the passivation layer 300 may be increased without significantly affecting the structural integrity of the corresponding device.

Further modifications, substitutions, additions and/or rearrangements to the above described embodiments and falling within the spirit and/or scope of the underlying inventive concept will be apparent to the person skilled in the art to provide further embodiments of the invention, any and all of which are intended to be encompassed by the appended claims.

1. A vertical cavity surface emitting laser comprising a substrate, a plurality of epitaxial layers disposed on said substrate to form an epitaxial stack and a passivation layer at least partly covering said epitaxial stack, said passivation layer comprising a first and a second sublayer with opposing stresses, the sublayers being disposed to reduce a net stress of said passivation layer and thereby to increase a mean time before the vertical surface emitting laser fails.

2. The vertical cavity surface emitting laser according to claim 1, wherein said first and second sublayers of said passivation layer comprise respective first and second materials wherein a stress of the first material is at least partially countered by a stress of the second material.

3. The vertical cavity surface emitting laser according to claim 2, wherein the stress of the first sublayer and the stress of the second sublayer are related to a thickness of the respective sublayer.

4. The vertical cavity surface emitting laser according to claim 3, wherein a thickness of said first sublayer is approximately twice a thickness of said second sublayer.

5. The vertical cavity surface emitting laser according to claim 1, wherein said first sublayer comprises SiOₓN_{y} (silicon oxynitride) and said second sublayer comprises SiNₓ (silicon nitride), arranged so that said first sublayer contacts said epitaxial stack and said second sublayer contacts said first sublayer.

6. The vertical cavity surface emitting laser according to claim 5, wherein the thickness of said first sublayer is between 200 nm and 480 nm and the thickness of said second sublayer is between 90 nm and 240 nm.

7. The vertical cavity surface emitting laser according to claim 6, wherein the thickness of the first sublayer is 220 nm and the thickness of the second sublayer is 110 nm.

8. The vertical cavity surface emitting laser according to claim 6, wherein a combined thickness of the first and the second sublayer is about 800 nm.

9. A method for producing a vertical cavity surface emitting laser comprising the steps of:
forming a plurality of epitaxial layers on a substrate to form an epitaxial stack;
at least partly covering said epitaxial stack with a passivation layer, said passivation layer comprising a first and a second sublayer with opposing stresses disposed to reduce a net stress of said passivation layer and thereby to increase a mean time before the vertical surface emitting laser fails.

10. The method according to claim 9, wherein said first and second sublayers of said passivation layer comprise respective first and second materials wherein a stress of the first material is at least partially countered by a stress of the second material.

11. The method according to claim 10, wherein the stress of the first sublayer and the stress of the second sublayer are related to a thickness of the respective sublayer and wherein said net stress of said passivation layer is reduced by setting the thickness of both of said first and said second sublayers.

12. The method according to claim 11, wherein a thickness of said first sublayer is approximately twice a thickness of said second sublayer.

13. The method according to claim 9, wherein said first sublayer comprises SiOₓN_{y} (silicon oxynitride) and a second sublayer comprises SiNₓ (silicon nitride), said method further comprising the steps of forming said first sublayer in contact with said epitaxial stack and forming said second sublayer in contact with said first sublayer.

14. The method according to claim 13, wherein the thickness of said first sublayer is between 200 nm and 480 nm and the thickness of said second sublayer is between 90 nm and 240 nm.

15. The method according to claim 14, wherein a thickness of the first sublayer is 220 nm and a thickness of the second sublayer is 110 nm.

16. The method according to claim 14, wherein a combined thickness of the first and the second sublayer is about 800 nm.

17. A method for passivating a vertical cavity surface (VCSEL) emitting laser comprising the steps of:
depositing a first sublayer comprising a first material with a first stress value on a surface of said VCSEL;
depositing a second sublayer comprising a second material with a second stress value on top of said first sublayer;
wherein the first and the second materials are chosen so that the first stress value counters the second stress value, the method further comprising the step of setting a thickness of the first sublayer and a thickness of the second sublayer.
